(19) United States
(12) Patent Application Publication
(10) Pub. No.: US 2006/0159283 A1
(43) Pub. Date: Jul. 20, 2006

(54) Method and apparatus for audio bass enhancement

(75) Inventors: Manu Mathew, Suwon-si (KR); Manish Arora, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTORNICS CO., LTD.

(21) Appl. No.: 11/257,123

(22) Filed: Oct. 25, 2005

(30) Foreign Application Priority Data
Jan. 14, 2005 (KR) 10-2005-0003801

(51) Int. Cl. H03G 5/00; H03G 3/00

(52) U.S. Cl. 381/98; 381/61

(57) ABSTRACT

A method and apparatus for audio bass enhancement is provided. The method includes band-pass filtering an input signal; generating at least one even and odd harmonics of the band-pass filtered input signal; and synthesizing the harmonics and the band-pass filtered input signal to be output.

This application claims the priority of Korean Patent Application No. 10-2005-0003801, filed on Jan. 14, 2005, in the Korean Intellectual Property Office, the disclosure of which is incorporated herein in its entirety by reference.

### BACKGROUND OF THE INVENTION

1. Field of the Invention

The present invention relates to an audio data process, and more particularly, to a method and apparatus for audio bass enhancement in audio reproduction.

2. Description of the Related Art

Audio data reproduced by a multimedia replay device, such as a CD or DVD player is output through a loudspeaker. The reproduced data's output fidelity to an original sound depends on the performance of the loudspeaker and the capacity of a player's audio processor. Developments in audio processing technology, however, have reduced the physical size of loudspeakers, imposing a physical limitation in faithfully reproducing the original sound's bass component.

Generally, a computer is coupled with a small-sized loudspeaker through which the computer's CD or DVD player may output a reproduced audio signal. A typical television is also equipped with a loudspeaker from which audio data aired from broadcasting stations is output. The small-sized loudspeakers coupled with the computer or equipped within the television have a problem in faithfully reproducing audio bass sounds, even if the quality of the sound data is excellent.

U.S. Pat. No. 5,930,373 teaches a method of generating harmonics through a feedback loop from an output to an input. This method is used along with a volume equalization process that enhances low-level signals to compensate for the non-linear characteristics of the human ear. Since the technology of audio bass enhancement in the context of non-linearity has been already patented, the present invention will not use non-linearity for audio bass enhancement.

U.S. Pat. Nos. 5,668,885 and 5,771,296 teach generating harmonics by using a rectifier arrangement to arrange absolute values. U.S. Pat. Nos. 4,150,253 and 4,700,390 teach generating harmonics by clipping. In addition, U.S. Pat. No. 6,792,115 teaches generating harmonics by using the high power of a band-pass filtered input signal.

A principle requirement of generating harmonics is to generate both even and odd harmonics. However, with a simple full-wave rectifier, only the even harmonics can be generated. This leads to a problem in which bass signals are perceived to have double the frequency as the original sound.

Another problem is that it is not possible to adjust spectral envelopes of harmonics using conventional methods. It is necessary to adjust the amplitude of harmonics, or to control the decay rate of higher harmonics. The decay rate of higher harmonics is a critical factor since it affects the timber of the perceived bass component of a sound.

Yet another problem is that the above methods are dependent upon signal levels. The spectral envelopes are different at different levels, and thus can lead to a problem in the feedback of generated harmonics at low levels. In the methods, signals can be scaled down or amplified, the position of a low frequency region to be enhanced is not fixed, and it is necessary for a harmonic generator to achieve independence from signal level. Moreover, the implementation of the methods is very complicated and computationally complex.

### SUMMARY OF THE INVENTION

The present invention provides a method and apparatus for audio bass enhancement by generating both even and odd harmonics of signals in a low frequency range.

According to an aspect of the present invention, there is provided a method of audio bass enhancement, comprising: band-pass filtering an input signal; generating at least one even and odd harmonics of the band-pass filtered input signal; and synthesizing the harmonics and the band-pass filtered input signal to be output.

According to an aspect of the present invention, generating at least one even and odd harmonics comprises: modulating the band-pass filtered input signal with at least one frequency signal; and band-pass filtering each of the modulated signals.

According to an aspect of the present invention, synthesizing the harmonics and the band-pass filtered input signal comprises, amplifying the band-pass filtered, modulated signals, and combining the resultants of the amplification and the band-pass filtered input signal amplified with a gain.

According to an aspect of the present invention, band-pass filtering an input signal passes only 25-75 Hz frequency range of the input signal.

According to an aspect of the present invention, modulating the band-pass filtered input signal with at least one frequency signal is performed with sinusoidal waves centered at 50 Hz, 100 Hz, 150 Hz, and 200 Hz.

According to an aspect of the present invention, band-pass filtering each of the modulated signals is performed by filtering the signal modulated to be centered at 50 Hz by a 75-125 Hz band-pass filter, filtering the signal modulated to be centered at 100 Hz by a 125-175 Hz band-pass filter, filtering the signal modulated to be centered at 150 Hz by a 175-225 Hz band-pass filter, and filtering the signal modulated to be centered at 200 Hz by a 225-275 Hz band-pass filter.

According to another aspect of the present invention, there is provided an apparatus for audio bass enhancement, comprising: a first band-pass filter that band-pass filters an input signal; a harmonic signal generator that generates at least one even and odd harmonics of the band-pass filtered input signal; and a signal synthesizer that synthesizes the harmonics and the band-pass filtered input signal to be output.

According to an aspect of the present invention, the harmonic signal generator comprises: at least one modulator that modulates the band-pass filtered input signal with at least one frequency signal; and at least one second band-pass filter that band-pass filters at least one modulated signal.

According to an aspect of the present invention, the signal synthesizer amplifies at least one signal resultant from band-pass filtering the at least one modulated signal, and combines the result of amplification, along with a resultant of amplifying the band-pass filtered input signal.

According to an aspect of the present invention, the first band-pass filter filters out all frequencies except those in the range of 25-75 Hz.

According to an aspect of the present invention, the at least one modulator performs modulation with sinusoidal waves centered at 50 Hz, 100 Hz, 150 Hz, and 200 Hz.

According to an aspect of the present invention, the at least one second band-pass filter comprises 75-125 Hz, 125-175 Hz, 175-225 Hz, and 225-275 Hz band-pass filters that filters signals modulated to be centered at 50 Hz, 100 Hz, 150 Hz, and 200 Hz, respectively.

According to still another aspect of the present invention, there is provided a computer-readable recording medium storing a program for a computer to execute the method as described above.

### BRIEF DESCRIPTION OF THE DRAWINGS

The above and other aspects and advantages of the present invention will become more apparent by describing in detail preferred embodiments thereof with reference to the attached drawings in which:

FIG. 1 shows a sound pressure level (SPL) response curve of a small-sized loudspeaker;

FIG. 2 shows an example of a missing fundamental effect;

FIG. 3 shows an example of an inter-modulation effect;

FIG. 4 is a schematic block diagram illustrating a psycho-acoustic bass enhancement circuit;

FIG. 5 shows an input signal, and output signals of a full wave rectifier and a full wave integrator;

FIG. 6 shows a frequency spectrum of the signals of FIG. 5;

FIG. 7 is a block diagram of a bass enhancement circuit, using single sideband suppressed carrier modulation, according to the present invention;

FIG. 8 is a spectrum of a 50 Hz sinusoidal wave;

FIG. 9 is a spectrum of an output signal of the bass enhancement circuit of FIG. 7 with a 50 Hz sinusoidal wave input; and

FIG. 10 is a flowchart illustrating a method of audio bass enhancement according to the present invention.

### DETAILED DESCRIPTION OF THE INVENTION

Exemplary embodiments of the present invention will now be described in detail with reference to the attached drawings.

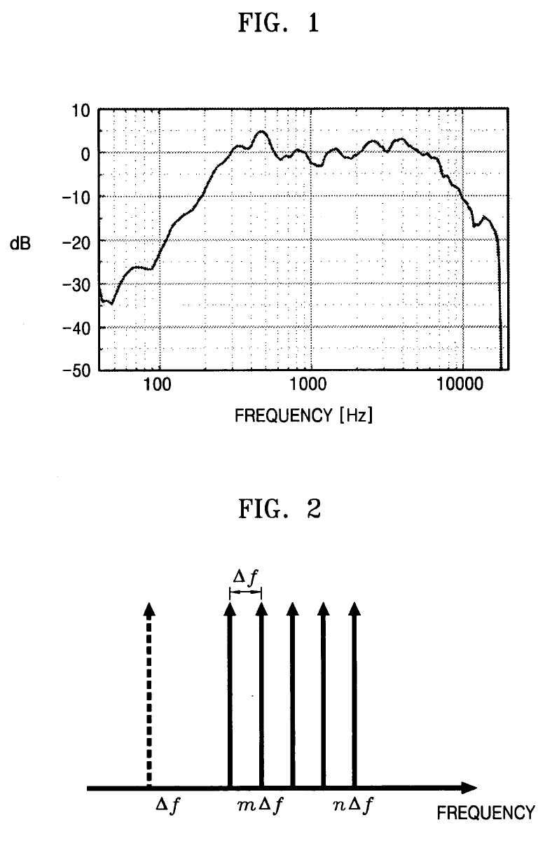

FIG. 1 shows a sound pressure level (SPL) response curve of a small-sized loudspeaker.

The small-sized loudspeaker has poor sound characteristics at low frequencies. The characteristics of a reproduced sound at low frequencies are related to the size of a transducer and to the wavelength of the sound. To obtain good characteristics at low frequencies, the size of the transducer should correspond to the wavelength. For example, for 20-300 Hz frequencies, the wavelength ranges from about 10-1 m. However, in practice, the size of the transducer is much smaller than the wavelength, thereby degrading low frequency output characteristics.

Referring to FIG. 1, it is noted that there is a 25-30 dB degradation in the low frequency range. To prevent this degradation, amplification (or gain) of the low frequency should be boosted. However, reckless gain boosting without considering the capabilities of the loudspeaker may damage the transducer, or adversely affect the overall gain. In addition, portable batteries, such as those in notebook computers, are insufficient to boost the gain as much as is desired.

Since the human ear does not sense the distortion of harmonics in the low frequency range very well, some parameters relevant to the distortion of harmonics in the low frequency range can be freely set. Psycho-acoustic technology using the nature of the human ear is employed by MPEG and Dolby AC-3 audio schemes. However, these conventional schemes have not yet introduced any idea of audio bass enhancement.

In the present invention, using psycho-acoustic technology relevant to pitch sensation, such as virtual pitch or virtual bass technology, signals in a low frequency range can be shifted into a medium frequency range where transducer response is relatively good, thereby improving the characteristics of the low frequency signal. Here, the pitch refers to a musical term that indicates humans' perception of sound wave frequency. As frequency decreases, the pitch becomes flat, and as frequency increases, the pitch becomes sharper.

FIG. 2 shows an example of a missing fundamental effect.

Most musical instruments produce sounds characteristic of those instruments by generating and combining a fundamental frequency and a sequence of several harmonics of the fundamental frequency. Combining the sequence of several harmonics enhances the frequency characteristics of the fundamental frequency.

For example, when a person makes a sound “ah . . . ” at 200 Hz, hearing membranes of the cochlea sense not only the sound of 200 Hz but also harmonics of 400, 600, 800, 1000, 1200 Hz, etc. Information of all the frequencies is conveyed to a hearing organ in the cerebrum and continuously affects the formation of the harmonic template by the temporal lobe cortex. When the harmonic information is received by the harmonic template in the cerebrum, the harmonic template extracts a fundamental sound of 200 Hz in the context of the relationship of the harmonics. In practice, even if only harmonics are heard, the fundamental frequency can be clearly perceived by the listener. This is referred to as a missing fundamental effect. Therefore, by using the missing fundamental effect to generate harmonics of frequencies in the bass range, signals in the bass range can be psycho-acoustically perceived.

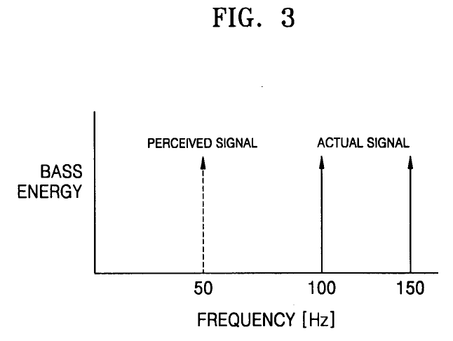

FIG. 3 shows another example of the missing fundamental effect.

Recently, various different methods of psycho-acoustic audio bass enhancement have been disclosed. In all of the methods, low frequency signals below a cut-off frequency of a loudspeaker are extracted, and harmonics of each of the extracted low frequencies are generated and combined with an actual sound. Referring to FIG. 3, the actual sound is subjected to high-pass filtering that only passes high frequency components above the cut-off frequency of the loudspeaker, in order to remove the low frequency components of the actual sound that could not be acoustically reproduced by the transducer. However, since the fundamental frequency can be perceived by the missing fundamental effect, the high-pass filtering process can be left out in a simple system.

The easiest way to generate harmonics of an input signal is to perform a nonlinear operation on the signal. The nonlinear operation generates harmonics dependent on the type of nonlinearity.

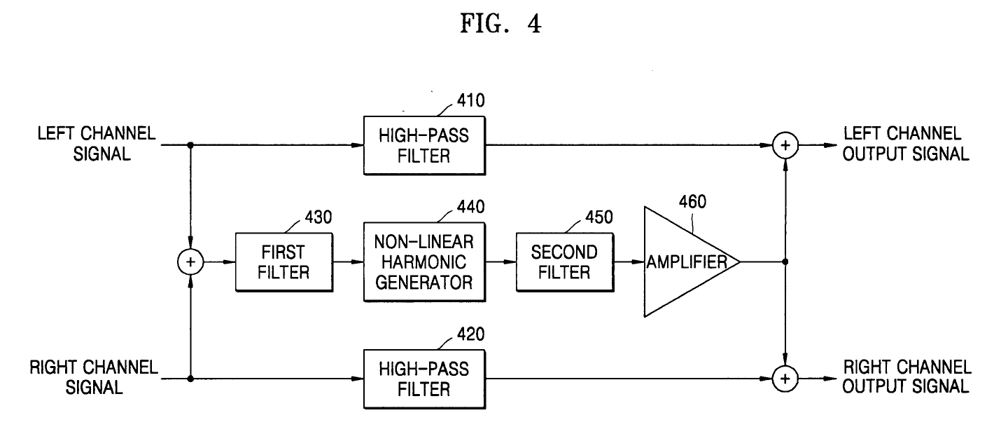

FIG. 4 is a schematic block diagram of a psycho-acoustic bass enhancement circuit.

Referring to FIG. 4, the bass enhancement circuit includes high-pass filters 410 and 420, a first filter 430, a nonlinear harmonic generator 440, a second filter 450, and an amplifier 460.

The first filter 430 extracts a low frequency signal from a combination of left-channel and right-channel signals. The nonlinear harmonics generator 440 generates nonlinear harmonics, which will be later explained in more detail. The second filter 450 filters the generated nonlinear harmonics to remove DC-components, harmonics or distortion components in the low frequency range. The second filter 450 is also used to form the shape of the harmonics generated by the non-linear harmonic generator 440. The amplifier 460 amplifies the filtered signal with a gain. The amplified signal output by the amplifier 460 is then combined with a left-channel signal filtered by the high-pass filter 410, and a right-channel signal output by the high-pass filter 420.

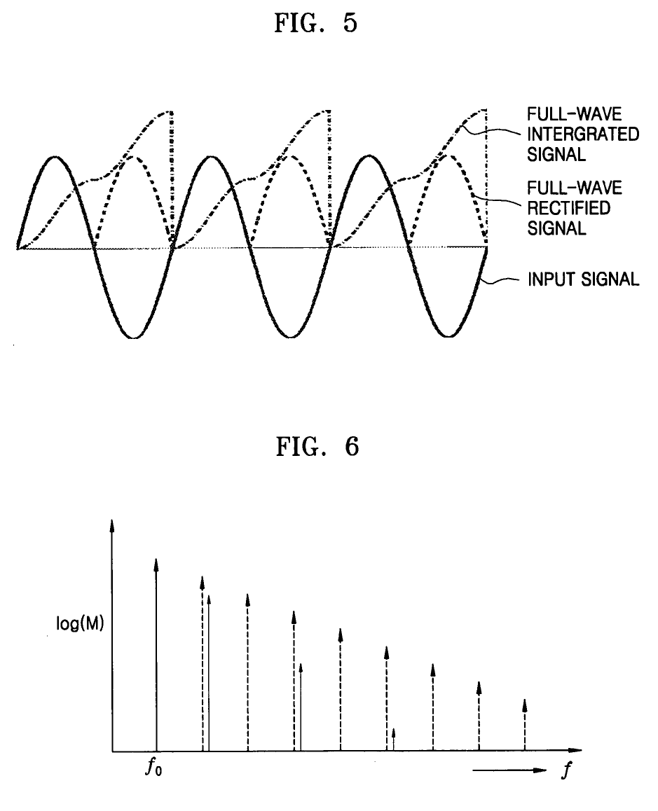

FIG. 5 shows an input signal, and output signals of a full wave rectifier and a full wave integrator.

A nonlinear method can be used to generate harmonics. For example, one of the simplest methods is to full-wave rectify an input signal. A full-wave rectification of the input signal creates harmonics of a frequency f of the input signal, such as 2f, 4f, 6f, etc. This method can be easily implemented. However, the method only generates even harmonics, as shown in FIG. 5, so the pitch corresponds to 2f, not to f. Referring to FIG. 5, harmonics can also be generated by a full-wave integration method. According to the full-wave integration method, the input signal is integrated and then discarded at the end of a cycle. The spectrum of the harmonics resulting from the full-wave integration method can be seen in FIG. 6.

FIG. 6 is a frequency spectrum of signals of FIG. 5.

Referring to FIG. 6, the higher the frequency, the lower the magnitude, and a signal has the maximum magnitude at the fundamental frequency fₒ.

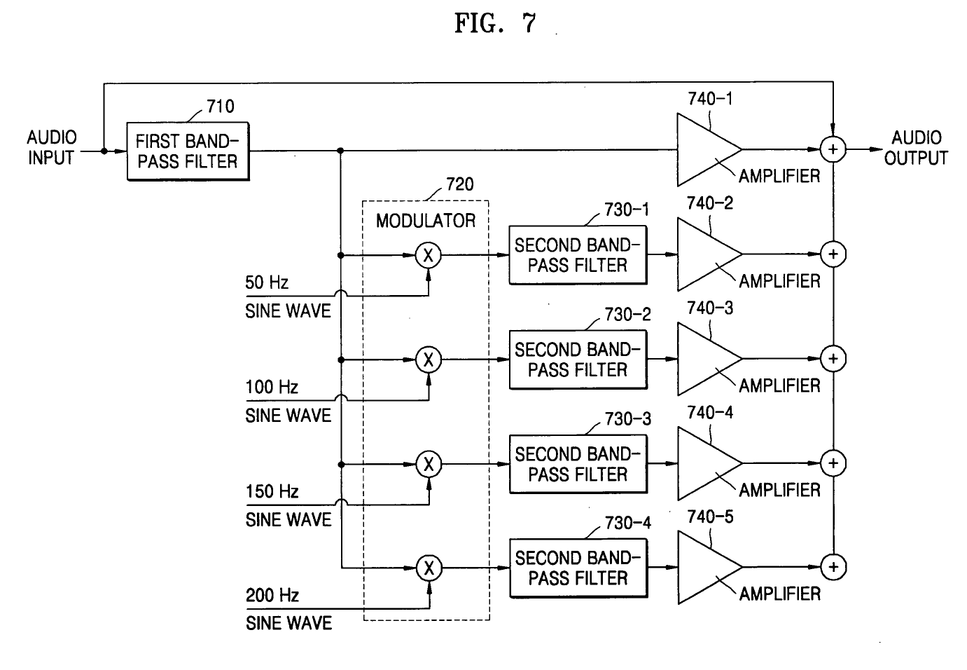

FIG. 7 is a block diagram of a bass enhancement circuit, using single sideband suppressed carrier modulation, according to the present invention.

The bass enhancement circuit comprises a first band-pass filter 710, a sinusoidal modulator 720, a plurality of second band-pass filters 730-1 through 730-4 and a plurality of amplifiers 740-1 through 740-5. The first band-pass filter 710 selects frequencies in the range of 25-75 Hz from an input signal. The sinusoidal modulator 720 modulates the input signal filtered by the first band-pass filter to various band signals centered at certain frequencies, such as 50 Hz, 100 Hz, 150 Hz, and 200 Hz. The plurality of second band-pass filters 730-1 through 730-4 each select a frequency from the signals output by the sinusoidal modulator 720, respectively. The plurality of amplifiers 740-1 through 740-5 amplify the resulting signals filtered by the second band-pass filters 730-1 through 730-4 with set gains. The gains are used to adjust the magnitude of harmonics components.

The 25-75 Hz frequency range, selected by the first band-pass filter 710, is referred to as a bass band. To generate harmonics of frequencies in the bass band, frequencies in the bass band should be modulated to be centered at various center frequencies. Multiplication by a real sinusoid, such as sin(ωt), creates two images, which corresponds to sidebands of amplitude modulation. One of the images is filtered out by a band-pass filter centered at a center frequency of a harmonic band. In other words, a signal modulated to be centered at 50 Hz is filtered by a 75-125 Hz band-pass filter, a signal modulated to be centered at 100 Hz is filtered by a 125-175 Hz band-pass filter, a signal modulated to be centered at 150 Hz is filtered by a 175-225 Hz band-pass filter, and a signal modulated to be centered at 200 Hz is filtered by a 225-275 Hz band-pass filter. And then, all the resultants from each filter are amplified with gains.

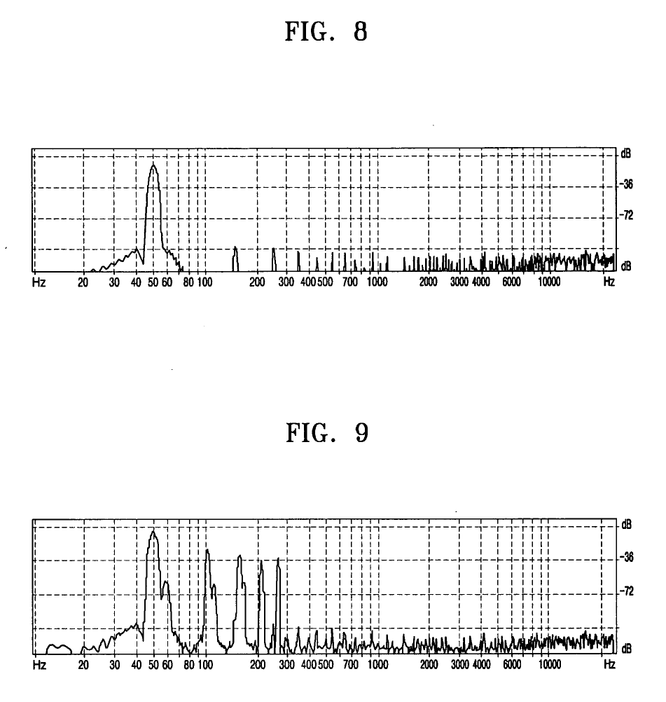

According to the above process, four different modulated, band-pass filtered, and amplified signals are combined to generate harmonics in the bass band. The modulator 720 and the plurality of second band-pass filters 730-1 through 730-4 are called together a harmonic signal generator. The amplifiers 740-1 through 740-5 and adders are called together a signal combiner. The band-pass filtered signals output by the second band-pass filters 730-1 through 730-4 are not exactly the harmonics in the bass band, however, their center frequencies have harmonic relations to the bass band. These harmonics will now be termed “pseudo harmonics”. It is necessary to accurately determine a gain for each of the pseudo harmonics. The gain is determined through listening experiments. For example, an experimenter can change the gain in real time using a GUI based application, while monitoring the bass enhancement effect. The positions of sliders for the best bass enhancement effect can be seen in FIG. 8. The maximum position of a slider corresponds to unity gain, and the minimum position of the slider corresponds to zero gain.

FIG. 8 shows a spectrum of a 50 Hz sinusoidal wave, and FIG. 9 shows a spectrum of an output signal of the bass enhancement circuit of FIG. 7 with 50 Hz sinusoidal wave input.

Referring to FIGS. 8 and 9, it is seen that the first four harmonics of the input 50 Hz sinusoidal wave signal are generated. The amplitude of each of the harmonics can be determined by adjusting the corresponding gain. For frequencies other than 50 Hz, the harmonic generation may not be perfect in that the harmonics would not be exact multiples of the fundamental frequency, but this does not cause significant problems.

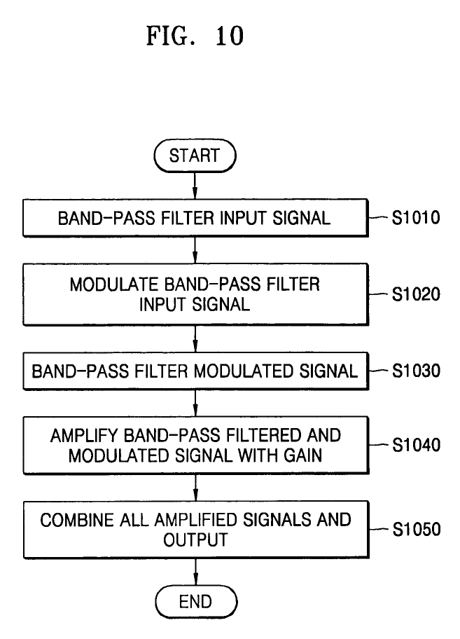

FIG. 10 is a flowchart illustrating a method of bass enhancement according to the present invention.

First, an input signal is band-pass filtered in operation S1010. Only the 25-75 Hz frequency band of the input signal is passed. The band-pass filtered signal is modulated in operation S1020. Sinusoidal waves centered at 50 Hz, 100 Hz, 150 Hz, and 200 Hz are used for the modulation. The four modulated signals are band-pass filtered again in operation S1030. A signal modulated to be centered at 50 Hz is filtered by a 75-125 Hz band-pass filter, a signal modulated to be centered at 100 Hz is filtered by a 125-175 Hz band-pass filter, a signal modulated to be centered at 150 Hz is filtered by a 175-225 Hz band-pass filter, and a signal modulated to be centered at 200 Hz is filtered by a 225-275 Hz band-pass filter. Each band-pass filtered signal is amplified with a gain in operation S1040, and all the amplified signals are combined and output in operation S1050.

According to the present invention as described above, bass enhancement by generating both even and odd harmonics of frequencies in a bass range is easily implemented and thus saves costs.

It is possible for the above-described method of audio bass enhancement according to the present invention to be implemented as a computer program. Codes and code segments constituting the computer program may readily be inferred by those skilled in the art. The computer programs may be recorded on computer-readable media and read and executed by computers. Such computer-readable media include all kinds of storage devices, such as ROM, RAM, CD-ROM, magnetic tape, floppy discs, optical data storage devices, etc. The computer readable media also include everything that is realized in the form of carrier waves, e.g., transmission over the Internet. The computer-readable media may be distributed to computer systems connected to a network, and codes on the distributed computer-readable media may be stored and executed in a decentralized fashion.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A method of audio bass enhancement, comprising:
band-pass filtering an input signal;
generating at least one even and odd harmonics of the band-pass filtered input signal; and
synthesizing the harmonics and the band-pass filtered input signal to be output.

2. The method of claim 1, wherein generating at least one even and odd harmonics comprises:
modulating the band-pass filtered input signal with at least one frequency signal; and
band-pass filtering each of the modulated signals.

3. The method of claim 2, wherein synthesizing the harmonics and the band-pass filtered input signal comprises:
amplifying the band-pass filtered, modulated signals, and combining the resultants of the amplification and the band-pass filtered input signal amplified with a gain.

4. The method of claim 2, wherein band-pass filtering an input signal passes only a 25-75 Hz frequency range of the input signal.

5. The method of claim 2, wherein modulating the band-pass filtered input signal with at least one frequency signal is performed with sinusoidal waves centered at 50 Hz, 100 Hz, 150 Hz, and 200 Hz.

6. The method of claim 2, wherein the modulated signals comprise a signal modulated to be centered at 50 Hz, a signal modulated to be centered at 100 Hz, a signal modulated to be centered at 100 Hz, a signal modulated to be centered at 150 Hz, and a signal modulated to be centered at 200 Hz, and wherein the band-pass filtering each of the modulated signals is performed by filtering the signal modulated to be centered at 50 Hz by a 75-125 Hz band-pass filter, filtering the signal modulated to be centered at 100 Hz by a 125-175 Hz band-pass filter, filtering the signal modulated to be centered at 150 Hz by a 175-225 Hz band-pass filter, and filtering the signal modulated to be centered at 200 Hz by a 225-275 Hz band-pass filter.

7. An apparatus for audio bass enhancement, comprising:
a first band-pass filter that band-pass filters an input signal;
a harmonic signal generator that generates at least one even and odd harmonics of the band-pass filtered input signal; and
a signal synthesizer that synthesizes the harmonics and the band-pass filtered input signal to be output.

8. The apparatus of claim 7, wherein the harmonic signal generator comprises:
at least one modulator that modulates the band-pass filtered input signal with at least one frequency signal; and
at least one second band-pass filter that band-pass filters at least one modulated signal.

9. The apparatus of claim 8, wherein the signal synthesizer amplifies at least one signal resultant from band-pass filtering the at least one modulated signal, and combines the result of amplification, along with a resultant of amplifying the band-pass filtered input signal.

10. The apparatus of claim 8, wherein the first band-pass filter filters out all frequencies except those in the range of 25-75 Hz.

11. The apparatus of claim 8, wherein the at least one modulator performs modulation with sinusoidal waves centered at 50 Hz, 100 Hz, 150 Hz, and 200 Hz.

12. The apparatus of claim 8, wherein the at least one modulated signal comprises a signal modulated to be centered at 50 Hz, a signal modulated to be centered at 100 Hz, a signal modulated to be centered at 100 Hz, a signal modulated to be centered at 150 Hz, and a signal modulated to be centered at 200 Hz, and wherein the at least one second band-pass filter comprises 75-125 Hz, 125-175 Hz, 175-225 Hz, and 225-275 Hz band-pass filters that filters the signals modulated to be centered at 50 Hz, 100 Hz, 150 Hz, and 200 Hz, respectively.

13. A computer-readable recording medium storing a program for a computer to execute the method of claim 1.
